(19) United States
(12) Patent Application Publication
(10) Pub. No.: US 2019/0244998 A1
(43) Pub. Date: Aug. 8, 2019

(54) IMAGING DEVICES, CAMERA MODULES, AND FABRICATION METHODS THEREOF

(71) Applicant: SHANGHAI JADIC OPTOELECTRONICS TECHNOLOGY CO., LTD, Shanghai (CN)

(72) Inventor: Xiaochuan WANG, Shanghai (CN)

(21) Appl. No.: 16/268,289

(22) Filed: Feb. 5, 2019

(30) Foreign Application Priority Data
Feb. 5, 2018 (CN) 201810113956.0

(51) Int. Cl. H01L 27/146; H01L 23/00

(52) U.S. Cl. CPC H01L 27/14634; H01L 27/14618; H01L 27/14621; H01L 27/14627; H01L 2224/48227; H01L 27/14645; H01L 24/48; H01L 27/14687; H01L 27/1469; H01L 27/14636

(57) ABSTRACT

An imaging device includes an image sensor chip. The image sensor chip includes a photosensitive surface and, opposite to the photosensitive surface, a bottom surface. The photosensitive surface includes a sensitive region, a peripheral transition region surrounding the photosensitive region, and an input/output wiring region surrounding the peripheral transition region. At least one input/output wiring pad is disposed in the input/output wiring region. The imaging device also includes a selective filter cover, disposed above the photosensitive region; and a retaining wall, disposed in the peripheral transition region and bonded to the selective filter cover. The retaining wall and the selective filter cover together form a closed cavity above the photosensitive region. The imaging device further includes a plurality of outgoing wires. A terminal of each outgoing wire is connected to an input/output wiring pad, and another terminal of the outgoing wire extends out from the image sensor chip.

### CROSS-REFERENCES TO RELATED APPLICATIONS

This application claims the priority of Chinese Patent Application No. CN201810113956.0, filed on Feb. 5, 2018, the entire content of which is incorporated herein by reference.

### FIELD OF THE DISCLOSURE

The present disclosure generally relates to the field of semiconductor fabrication technology and, more particularly, relates to imaging devices, camera modules, and fabrication methods thereof.

### BACKGROUND

Compared with the charge-coupled device (CCD) camera module, the complementary metal-oxide-semiconductor (CMOS) camera module (CCM) demonstrates the advantages of small size and low power consumption. Today, high-performance, miniaturized CMOS camera modules and the corresponding image processing functions have become essential ingredients for smartphones. In addition, with intelligent identification functions, three-dimensional (3D) imaging cameras of mobile phones have also entered the commercial application stage. The resolution of these miniaturized CMOS camera modules is further enhanced and, combined with an improved micro-system packaging process, these miniaturized CMOS camera modules become necessary components for smart phones to become thinner and lighter.

At present, a CMOS camera module that contains a high-resolution CMOS image sensor chip is usually assembled based on a chip on board (COB) packaging process. In the CMOS camera module, a color micro-filter array and a micro-lens array arranged on the top of the color micro-filter array are disposed on the top of the photosensitive region of the CMOS image sensor. Since the color micro-filter array and the micro-lens array are both made of a polymer, it may not be easy to use any traditional package cleaning method to remove the remaining and residual dust or other foreign objects. Therefore, once dust or other foreign objects are left on the photosensitive region of a CMOS image sensor chip during the entire COB packaging process and the subsequent module assembly process, the overall production yield of the CMOS camera module may be seriously affected. The disclosed imaging devices, camera modules, and fabrication methods thereof are directed to solve one or more problems set forth above and other problems in the art.

### BRIEF SUMMARY OF THE DISCLOSURE

One aspect of the present disclosure provides an imaging device. The imaging device includes an image sensor chip. The image sensor chip includes a photosensitive surface and, opposite to the photosensitive surface, a bottom surface. The photosensitive surface includes a sensitive region, a peripheral transition region surrounding the photosensitive region, and an input/output wiring region surrounding the peripheral transition region. At least one input/output wiring pad is disposed in the input/output wiring region. The imaging device also includes a selective filter cover, disposed above the photosensitive region; and a retaining wall, disposed in the peripheral transition region and bonded to the selective filter cover. The retaining wall and the selective filter cover together form a closed cavity above the photosensitive region. The imaging device further includes a plurality of outgoing wires. A terminal of each outgoing wire is connected to an input/output wiring pad, and another terminal of the outgoing wire extends out from the image sensor chip.

Another aspect of the present disclosure provides a camera module. The camera module includes an imaging device according to the present disclosure.

Another aspect of the present disclosure provides a fabrication method for an imaging device. The fabrication method includes providing a bottom wafer including a first surface. The first surface of the bottom wafer includes a plurality of image sensor chips. Each image sensor chip including a photosensitive surface and, opposite to the photosensitive surface, a bottom surface. The first surface is the photosensitive surface. The photosensitive surface includes a sensitive region, a peripheral transition region surrounding the photosensitive region, and an input/output wiring region surrounding the peripheral transition region. At least one input/output wiring pad is disposed in the input/output wiring region. The fabrication method includes providing a selective filter wafer, including a second surface and a third surface; and forming a plurality of retaining walls. The plurality of retaining walls are formed on the second surface of the selective filter wafer with a number and a size corresponding to the number and the size of the image sensor chips disposed on the first surface of the bottom wafer, respectively, or on the first surface of the bottom wafer in the peripheral transition regions of the plurality of image sensor chips. The fabrication method also includes bonding the first surface of the bottom wafer to the second surface of the selective filter wafer. The bottom wafer, the selective filter wafer, and the plurality of retaining walls together form a plurality of closed cavities above the photosensitive region. The fabrication method further includes removing a portion of the selective filter wafer located outside of the plurality of retaining walls to expose the input/output wiring region of each image sensor chip and form a selective filter cover corresponding to the image sensor chip; cutting the bottom wafer and the selective filter wafer to obtain a plurality of individual imaging devices; and providing outgoing wires for an imaging device. Each outgoing wire includes a lead-in terminal and a lead-out terminal. The lead-in terminal of an outgoing wire is connected to an input/output wiring pad, and the lead-out terminal of the out-going wire extends out from the image sensor chip.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrating various embodiments and are not intended to limit the scope of the present disclosure. The above and other objects, features, and advantages of the present disclosure will become more apparent from the following detailed description of the embodiments of the present disclosure with reference to the accompanying drawings. In the embodiments of the present disclosure, a same reference number generally refers to a same component.

FIG. 1 illustrates schematic views of semiconductor structures at certain stages of an assembly process for a CMOS camera module;

FIG. 2 illustrates a schematic structural view of an exemplary imaging device according to embodiments of the present disclosure;

FIG. 3 illustrates a schematic structural view of another exemplary imaging device according to embodiments of the present disclosure;

FIG. 4A and FIG. 4B illustrate a front view and a top view, respectively, of another exemplary imaging device according to embodiments of the present disclosure;

FIGS. 5A-5G illustrate schematic views of semiconductor structures at certain stages of an exemplary method for fabricating an imaging device according to embodiments of the present disclosure; and

FIG. 6 illustrates a flowchart of an exemplary method for fabricating an imaging device according to embodiments of the present disclosure.

### DESCRIPTION OF THE REFERENCE NUMBERS

50 bottom wafer, 51 first surface, 60 selective filter wafer, 100 image sensor chip, 101 photosensitive surface, 102, bottom surface, 110 photosensitive region, 111 color filter array, 115 micro-lens array, 120 peripheral transition region, 130 input/output wiring region, 131 input/output wiring pad, 140 scribed line of the wafer, 210 selective filter cover, 220 retaining wall, 230 closed cavity, 250 outgoing wire, 300 carrier board, 310 receiving-board wiring pad, 410 auxiliary device, 411 top wiring pad, 500 side carrier board, 510 insulating carrier.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

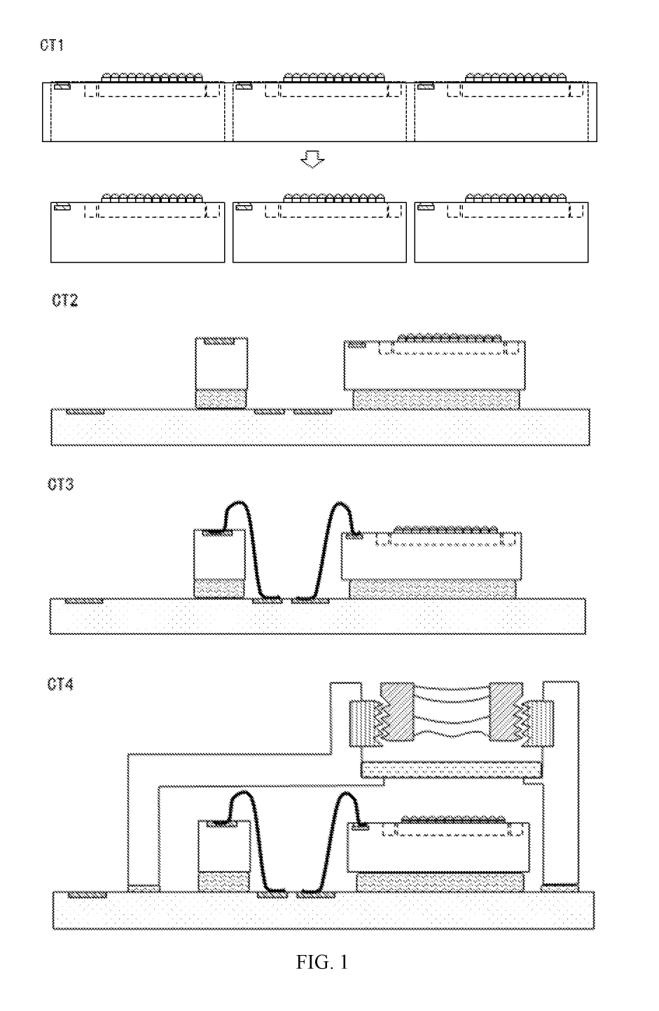

FIG. 1 illustrates schematic views of semiconductor structures at certain stages of an existing assembly process for a CMOS camera module. Referring to FIG. 1, the assembly process includes the following steps:

CT1: cutting a wafer of CMOS image sensor chips into a plurality of separate CMOS image sensor chips;

CT2: attaching an individual CMOS image sensor chip and auxiliary devices to a base substrate, the base substrate including a multi-layer printed circuit board (PCB) or a flexible printed circuitry (FPC);

CT3: forming interconnections between the CMOS image sensor chip, the auxiliary devices, and the base substrate through wire bonding;

CT4: placing and sealing a prefabricated modular assembly of lens holder and lens on the top of the CMOS image sensor chip, the modular assembly of lens holder and lens including a lens group composed of two or more independent lenses from top to bottom, a micro focus motor, and an infrared filter.

It should be noted that the surface of the CMOS image sensor chip, serving as the core device, contains the most sensitive photosensitive region of the chip. During the COB packaging process, and also in each step (CT1, CT2, CT3 and CT4) of the subsequent module assembly process as well as between different steps, dust or other foreign objects falling into and remaining in the photosensitive region of the chip will seriously affect the photosensitive and imaging functions, becoming an important factor that leads to reduction of the yield in mass production of CMOS camera module assembly based on the COB packaging. However, since a color micro-filter array together with a micro-lens array arranged on the top of the color micro-filter array are disposed on the top of the photosensitive region of the CMOS image sensor, and the color micro-filter and the micro-lens are both made of a polymer, it may not be easy to use traditional package cleaning methods to remove the remaining and residual dust or other foreign objects. Therefore, once dust or other foreign objects are left on the photosensitive region of a CMOS image sensor chip during the entire COB packaging and subsequent module assembly process, the overall production yield of the CMOS camera module will be seriously affected.

To improve the production yield of the CMOS camera module, the present disclosure provides an imaging device. The imaging device may include an image sensor chip, and the image sensor chip may include a photosensitive surface and, opposite to the photosensitive surface, a bottom surface. The photosensitive surface may include a photosensitive region, a peripheral transition region surrounding the photosensitive region, and an input/output wiring region surrounding the peripheral transition region. At least one input/output wiring pad may be disposed in the input/output wiring region. The imaging device may also include a selective filter cover disposed above the photosensitive region of the chip, a retaining wall disposed in the peripheral transition region and bonded to the selective filter cover to form a closed cavity, and a plurality of outgoing wires of the chip. A terminal of each outgoing wire may be connected to an input/output wiring pad and the other terminal may be extended out from the image sensor chip.

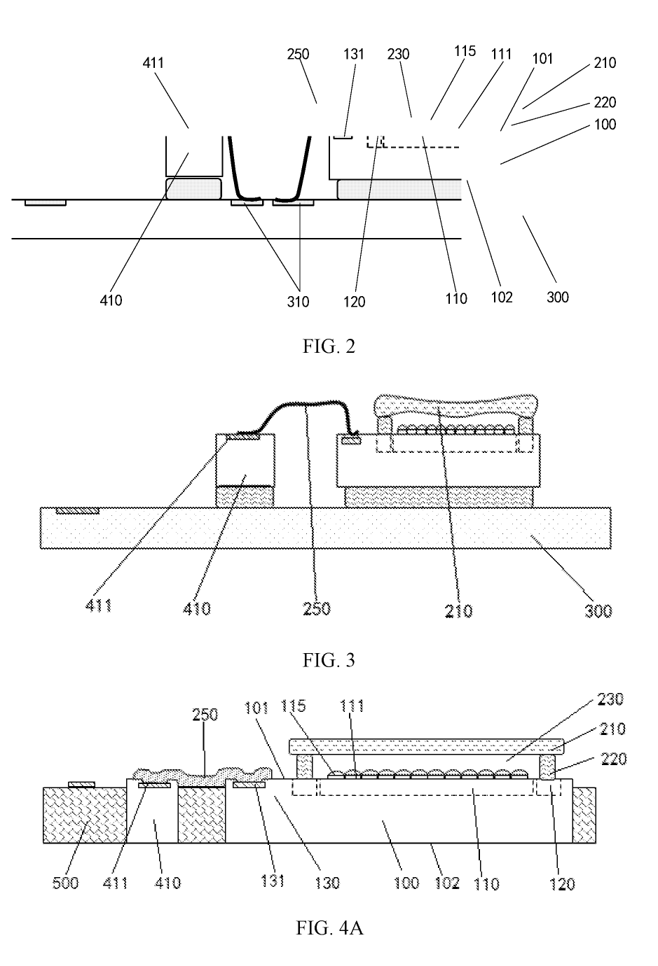

FIG. 2 illustrates a schematic structural view of an exemplary imaging device according to embodiments of the present disclosure. Referring to FIG. 2, the imaging device may include an image sensor chip 100. The image sensor chip 100 may include a photosensitive surface 101 and, opposite to the photosensitive surface 101, a bottom surface 102. The photosensitive surface 101 may include a photosensitive region 110, a peripheral transition region 120 surrounding the photosensitive region 110, and an input/output wiring region 130 surrounding the peripheral transition region 120. In addition, at least one input/output wiring pad 131 may be disposed in the input/output wiring region 130.

The imaging device may include a selective filter cover 210. The selective filter cover 210 may be disposed above the photosensitive region 110 of the chip.

The imaging device may also include a retaining wall 220. The retaining wall 220 may be disposed in the peripheral transition region 120 and may be bonded to the selective filter cover 210 to form a closed cavity 230.

The imaging device may further include a plurality of outgoing wires 250 of the chip. For illustrative purposes, only one outgoing wire 250 is shown in FIG. 2 although the imaging device may include more than one outgoing wires 250. A terminal of each outgoing wire 250 may be connected to each input/output wiring pad 131 and the other terminal may be extended out from the image sensor chip 100.

The imaging device may be used to form a camera module through a subsequently-performed assembly process.

An image sensor is a semiconductor device that converts an optical image into electronic signals. In one embodiment, the image sensor chip may be a complementary metal-oxide-semiconductor (CMOS) image sensor (CIS) chip. In other embodiments, the image sensor chip may be charge-coupled device (CCD) image sensor chip.

In one embodiment, the selective filter cover 210 may be used to block or absorb some or all external radiation in the infrared-band range to prevent the infrared-band radiation from entering the photosensitive region 110 of the chip. In the meantime, the selective filter cover 210 may be able to allow some or all radiation in the visible-light range to enter the photosensitive region 110 of the chip. Depending on the application of the imaging device, a selective filter cover 210 may be configured to block radiation with different wavelengths from entering the photosensitive region 110 of the chip.

In one embodiment, according to the actual process conditions, the selective filter cover 210 may include a red-green-blue (RGB) filter film. That is, the filter film may include a red filter film, a green filter film, and a blue filter film. The selective filter cover 210 may be configured to allow light with different wavelengths to pass. As such, light with a specific wavelength may be able to pass through the selective filter cover 210 and enter the photosensitive region 110 of the chip. Therefore, the probability of crosstalk may be reduced, and thus the imaging sensitivity may be improved.

In one embodiment, the material of the selective filter cover 210 may be a dyed polymer produced by a dyeing method. Because the dyeing method demonstrates desired image accuracy and high color contrast, the selective filter cover 210 may have desired analyticity and dye affinity. In addition, the selective filter cover 210 may also demonstrate advantages of high light transmittance and high color purity that are conducive to improving the optical performance and the yield of the image sensor chip 100.

In one embodiment, the selective filter cover 210 may selectively block or absorb some or all external radiation in the infrared-band range to substantially reduce the infrared-band radiation that enters the photosensitive region 110 of the chip. In one embodiment, the infrared-band radiation entering the photosensitive region 110 may be lower than 10% of the total infrared-band radiation.

In one embodiment, a color filter array 111 may be disposed on the surface of the photosensitive region 110 to improve the resolution of the imaging device. For example, the color filter array 111 may include a plurality of primary color filter units, and the primary color filter units may include red, green, and blue primary color filter units, or include magenta, yellow, and cyan primary color filter units. In some embodiments, the color filter array 111 may be made of a dyed polymer. For example, the polymer may be dyed to form a plurality of red, green, and blue primary color filter units, or form a plurality of magenta, yellow, and cyan primary color filter units.

In one embodiment, a micro-lens array 115 may be disposed on the surface of the photosensitive region 110, and the micro-lens array 115 may include a plurality of micro-focus lenses. The micro-lens array may be an array of lenses with micrometer-scaled apertures and relief depths, and may have desired functions for collecting, collimating, splitting, imaging, etc. In addition, because the diameter of a single micro-lens is small and the lens density is high, multi-channel parallel processing for information with an extensive volume may be implemented. In some embodiments, the plurality of micro-focus lenses may be made of a polymer, such as polyimide. The plurality of micro-focus lenses may have a high light transmittance, which is conducive to improving the optical performance and the yield of the image sensor chip 100.

In one embodiment, the retaining wall 220 may selectively block or absorb some or all external radiation in the infrared-band range to substantially reduce the infrared-band radiation that enters the photosensitive region 110 along a horizontal direction. The horizontal direction may refer to the direction parallel to the photosensitive surface 101. In one embodiment, the infrared-band radiation entering the photosensitive region 110 along the horizontal direction may be lower than 10% of the total infrared-band radiation in the horizontal direction.

In one embodiment, the imaging device may also include a carrier board 300. A plurality of receiving-board wiring pads 310 may be arranged on the carrier board 300. The image sensor chip 100 may be stuck to the carrier board 300 with the bottom surface 102 facing the carrier board, and the lead-out terminal of an outgoing wire 250 may be connected to a receiving-board wiring pad 310.

In one embodiment, the imaging device may also include a plurality of auxiliary devices 410. For illustrative purposes, only one auxiliary device 410 is shown in FIG. 2 although the imaging device may include more than one auxiliary device 410. A top wiring pad 411 may be formed on the top of each auxiliary device 410, and the auxiliary device 410 may be stuck to the carrier board 300 with the top wiring pad 411 facing a direction away from the carrier board 300. The top wiring pad 411 may be connected to a receiving-board wiring pad 310 through a wire. In one embodiment, the auxiliary device 410 may be a passive device such as a capacitor, an inductor, a resistor, etc. In other embodiments, the auxiliary device 410 may be a semiconductor peripheral auxiliary circuit chip, such as a voice coil motor (VCM) drive circuit chip, or an application specific integrated circuit chip that is configured to execute optical correction and calibration for a module and store the corrected and calibrated parameters.

Further, in one embodiment, an assembly of lens holder and lens may be disposed on the carrier board 300 to form a camera module. The assembly of lens holder and lens may include a lens holder, a lens group, and a micro focus motor. The lens holder may be used to support the lens group. The lens group may include at least two independent lenses, and each lens may be a focus-fixed lens or a zoom lens. When focusing, the micro focus motor may drive the lens to move, such that the focus of the lens may be changed, and thus a clear image may be obtained.

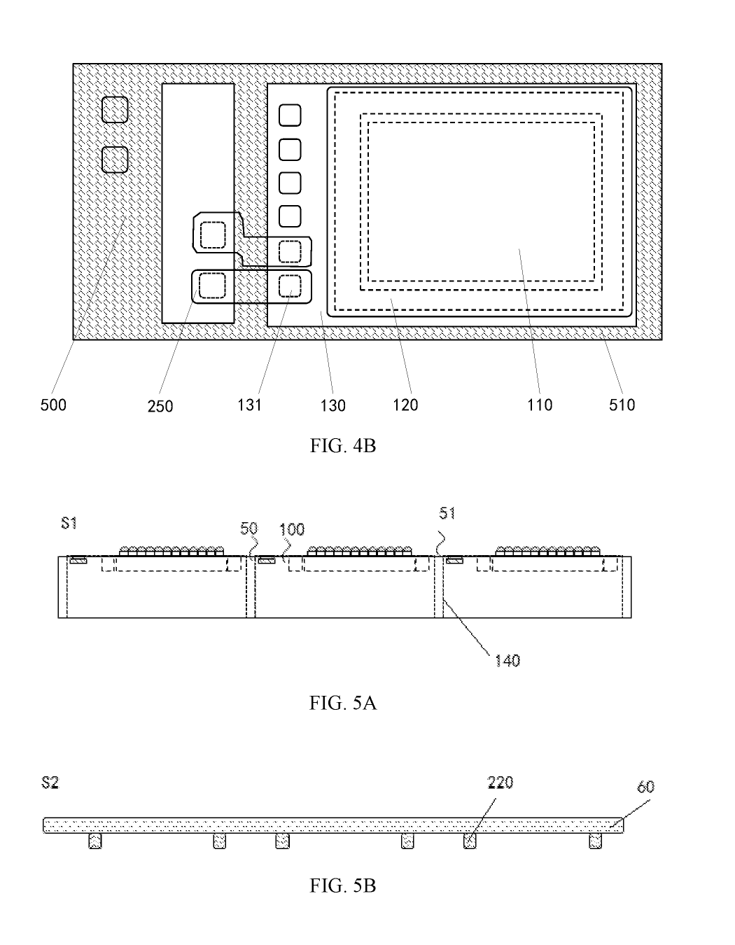

FIG. 3 illustrates a schematic structural view of another exemplary imaging device according to embodiments of the present disclosure. Different from the imaging device in the embodiment described above, the imaging device in the embodiment described here may include an anti-reflection film disposed on the surface of the selective filter cover 210 for reducing the reflection of the radiation in the visible-light range. The anti-reflection film may reduce the intensity of the reflection light, increase the intensity of the transmitted light, and thus make the imaging result clearer. In addition, the selective filter cover 210 may also be able to refract the visible light to assist the lenses in the lens group of the camera module to partially realize the optical modulation function. In other words, the selective filter cover 210 may be not only an infrared filter, but also an optical lens placed at the bottom of the lens group.

Further, in one embodiment, no receiving-board wiring pad may be disposed on the carrier board 300, and the lead-out terminal of each outgoing wire 250 may be directly connected to the top wiring pad 411 on an auxiliary device 410.

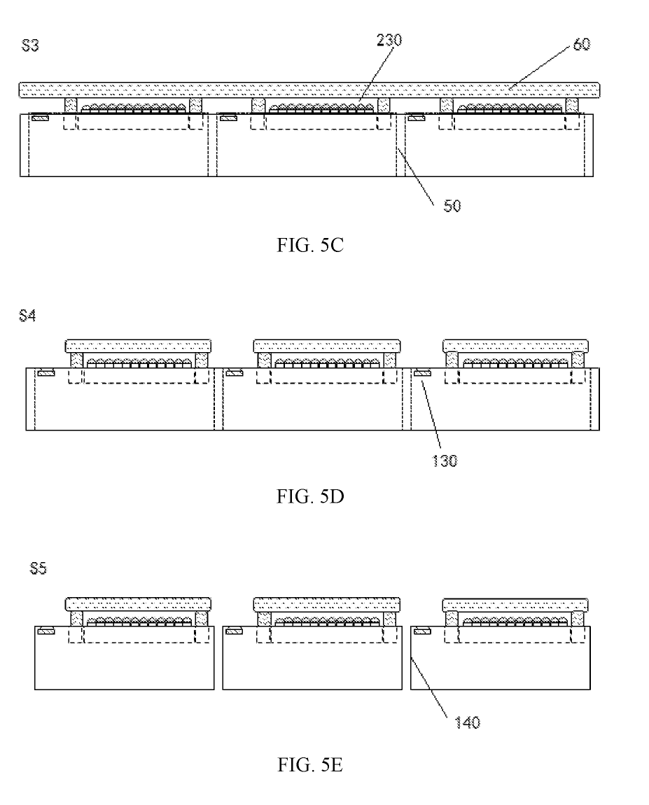

FIG. 4A and FIG. 4B illustrate a front view and a top view, respectively of another exemplary imaging device according to embodiments of the present disclosure. Referring to FIG. 4A and FIG. 4B, the imaging device may include an image sensor chip 100. The image sensor chip 100 may include a photosensitive surface 101 and, opposite to the photosensitive surface 101, a bottom surface 102. The photosensitive surface 101 may include a photosensitive region 110, a peripheral transition region 120 surrounding the photosensitive region 110, and an input/output wiring region 130 surrounding the peripheral transition region 120. In addition, at least one input/output wiring pad 131 may be disposed in the input/output wiring region 130.

The imaging device may include a selective filter cover 210. The selective filter cover 210 may be disposed above the photosensitive region 110 of the chip.

The imaging device may include a retaining wall 220. The retaining wall 220 may be disposed in the peripheral transition region 120 and bonded to the selective filter cover 210 to form a closed cavity 230.

The imaging device may also include a plurality of outgoing wires 250 of the chip. For illustrative purposes, only one outgoing wire 250 is shown in FIG. 4A although the imaging device may include more than one outgoing wires 250. A terminal of each outgoing wire 250 may be connected to each input/output wiring pad 131 and the other terminal may be extended out from the image sensor chip 100.

In one embodiment, a color filter array 111 and a micro-lens array 115 may be disposed on the surface of the photosensitive region 110 of the chip.

In one embodiment, the imaging device may also include a side carrier board 500. The side carrier board 500 may include a plurality of auxiliary devices 410 and an insulating carrier 510 surrounding the image sensor chip 100 and the plurality of auxiliary devices 410. A top wiring pad 411 may be disposed on the top of each auxiliary device 410. The lead-out terminal of an outgoing wire 250 may be connected to a top wiring pad 411 through the surface of the side carrier board 500.

In one embodiment, a principle of “fan-out” interconnection of leads in semiconductor chip may be applied to the system packaging process for the imaging device and the system assembly process for the corresponding camera module. Similarly, in one embodiment, after the selective filter cover 210 is disposed on the photosensitive region 110, the possibility for dust or other foreign objects to fall into the photosensitive region of the chip in subsequent processes may be substantially suppressed. Even dust or other foreign objects did fall onto the top surface of the selective filter cover 210, subsequently cleaning and removing the dust or other foreign objects may be easy.

The present disclosure further provides a camera module. The camera module may include an imaging device consistent with some embodiments described above. The camera module may also include an assembly of lens holder and lens. The assembly of lens holder and lens may include a lens holder, a lens group, and a micro focus motor. The lens holder may be used to support the lens group. The lens group may include at least two independent lenses, and each lens may be a focus-fixed lens or a zoom lens. When focusing, the micro focus motor may drive the lens to move, such that the focus of the lens may be changed, and thus a clear image may be obtained.

The present disclosure also provides a method for fabricating imaging devices. The method may include the following steps.

A bottom wafer may be provided. A plurality of image sensor chips may be disposed on a first surface of the bottom wafer, and the first surface of the bottom wafer may be the photosensitive surface of the chip.

A selective filter wafer may be provided. The selective filter wafer may include a second surface and a third surface.

A plurality of retaining walls may be formed on the second surface of the selective filter wafer. The number and the size of the retaining walls may correspond to the number and the size of the image sensor chips on the first surface of the bottom wafer, respectively.

The second surface of the selective filter wafer may be bonded to the first surface of the bottom wafer, such that a plurality of closed cavities, corresponding to the plurality of image sensor chips, may be formed above the photosensitive region of the chip.

The portion of the selective filter wafer located outside of the retaining walls may be removed to expose the input/output wiring regions of the image sensor chips. In the meantime, a plurality of selective filter covers may be formed from the selective filter wafer.

The bonded bottom wafer and selective filter wafer may be cut into a plurality of individual imaging devices.

For each imaging device, a plurality of outgoing wires may be provided for the chip. Each outgoing wire of the chip may include a lead-in terminal and a lead-out terminal. The lead-in terminal of the outgoing wire may be connected to an input/output wiring pad, and the lead-out terminal of the outgoing wire of chip may extend out from the image sensor chip. As such, an imaging device may be obtained.

The fabrication method for the imaging device may adopt a more efficient and lower cost wafer-level packaging method. Prior to cutting the plurality of image sensor chips into individual image sensor chips, a selective filter wafer may be placed onto the bottom wafer to prevent external dust and other foreign objects from falling into the photosensitive region of the chip and thus affecting the photosensitive and imaging functions during subsequent packaging and assembly processes. When cutting the plurality of image sensor chips into individual image sensor chips, a plurality of selective filter covers may be formed from the selective filter wafer. Therefore, in the subsequent manufacturing process, even dust or other foreign objects fall down, the dust or other foreign objects may fall onto the outer surface of the selective filter cover, and may be removable through various cleaning methods. Therefore, the production yield may be improved.

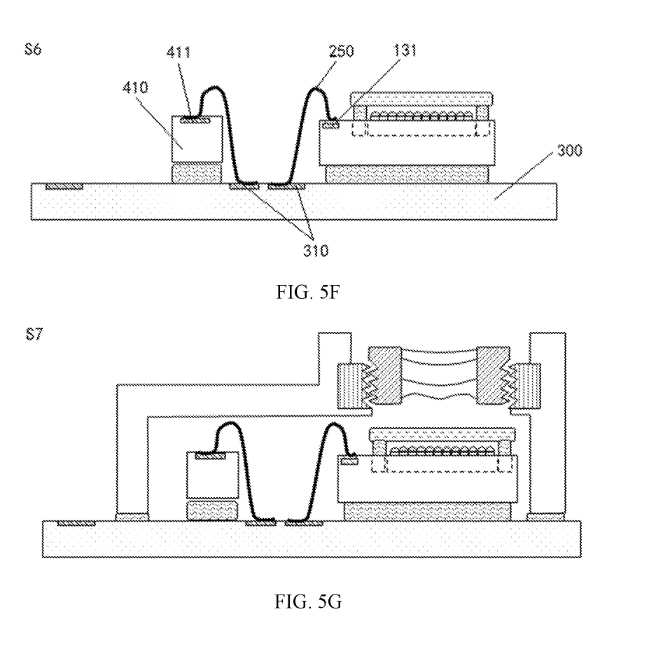

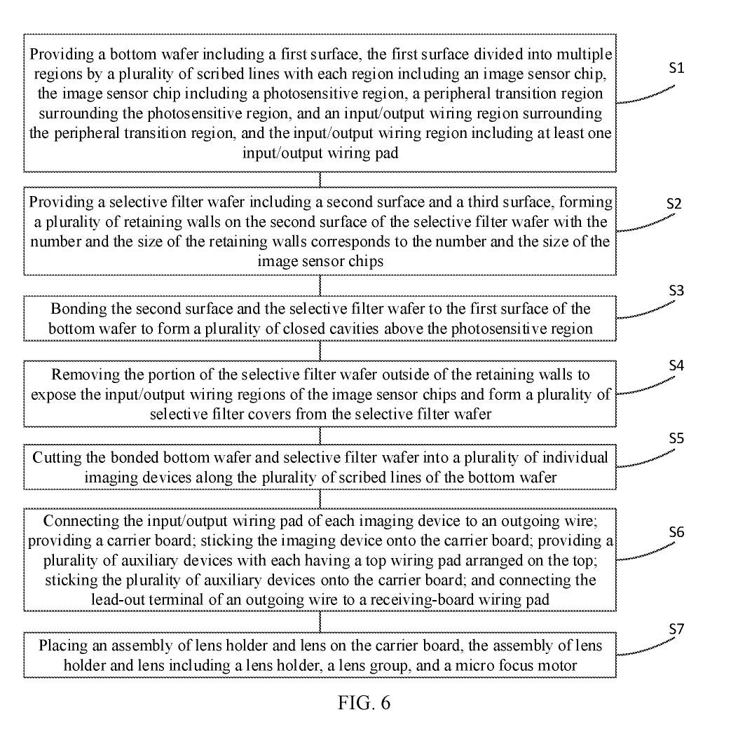

FIG. 6 illustrates a flowchart of an exemplary method for fabricating an imaging device according to embodiments of the present disclosure, and FIGS. 5A-5G illustrate schematic views of semiconductor structures at certain stages of the exemplary fabrication method.

Referring to FIG. 6, in step S1, a bottom wafer may be provided, a first surface of the bottom wafer may be divided into multiple regions by a plurality of scribed lines with each region including an image sensor chip, the first surface may be a photosensitive surface of the image sensor chip, and each image sensor chip may include a photosensitive region, a peripheral transition region surrounding the photosensitive region, and an input/output wiring region, surrounding the peripheral transition region and including at least one input/output wiring pad. FIG. 5A illustrates a schematic cross-section view of a corresponding semiconductor structure consistent with some embodiments of the present disclosure.

Referring FIG. 5A, a bottom wafer 50 may be provided. A first surface 51 of the bottom wafer may be divided into multiple regions by a plurality of scribed lines 140. An image sensor chip 100 may be disposed in each region, and the first surface 51 may be the photosensitive surface of the image sensor chip 100. Each image sensor chip 100 may include a photosensitive region, a peripheral transition region surrounding the photosensitive region, and an input/output wiring region surrounding the peripheral transition region. At least one input/output wiring pad may be disposed in the input/output wiring region.

Returning to FIG. 6, in step S2, a selective filter wafer, including a second surface and a third surface, may be provided, a plurality of retaining walls may be formed on the second surface of the selective filter wafer, and the number and the size of the retaining walls may correspond to the number and the size of the image sensor chips, respectively. FIG. 5B illustrates a schematic cross-section view of a corresponding semiconductor structure consistent with some embodiments of the present disclosure.

Referring to FIG. 5B, a selective filter wafer 60 may be provided. The selective filter wafer 60 may include a second surface and a third surface. A plurality of retaining walls 220 may be formed on the second surface of the selective filter wafer 60. The number and the size of the retaining walls 220 may correspond to the number and the size of the image sensor chips 100.

Further, returning to FIG. 6, in step S3, the second surface of the selective filter wafer may be bonded to the first surface of the bottom wafer to form a plurality of closed cavities above the photosensitive region of the chip. FIG. 5C illustrates a schematic cross-section view of a corresponding semiconductor structure consistent with some embodiments of the present disclosure.

Referring to FIG. 5C, the second surface of the selective filter wafer 60 may be bonded to the first surface of the bottom wafer 50 to form a plurality of closed cavities 230 above the photosensitive region of the chip.

Further, returning to FIG. 6, in step S4, the portion of the selective filter wafer outside of the retaining walls may be removed to expose the input/output wiring regions of the image sensor chips, and thus a plurality of selective filter covers may be formed from the selective filter wafer. FIG. 5D illustrates a schematic cross-section view of a corresponding semiconductor structure consistent with some embodiments of the present disclosure.

Referring to FIG. 5D, the portion of the selective filter wafer 60 outside of the retaining walls 220 may be removed to expose the input/output wiring regions 130 of the image sensor chips 100. In the meantime, a plurality of selective filter covers may be formed from the selective filter wafer 60.

Returning to FIG. 6, in step S5, the bonded bottom wafer and selective filter wafer may be cut into a plurality of individual imaging devices along the plurality of scribed lines of the bottom wafer. FIG. 5E illustrates a schematic cross-section view of a corresponding semiconductor structure consistent with some embodiments of the present disclosure.

Referring to FIG. 5E, the bonded bottom wafer and selective filter wafer may be cut into a plurality of individual imaging devices along the plurality of scribed lines 140 of the bottom wafer.

Returning to FIG. 6, in step S6, an input/output wiring pad of each imaging device may be connected to an outgoing wire; a carrier board including a plurality of receiving-board wiring pads may be provided, and the imaging device may be stuck onto the carrier board with the bottom surface facing to the carrier board; a plurality of auxiliary devices, each having a top wiring pad arranged on the top, may be stuck to the carrier board with the back surfaces of the auxiliary devices facing to the carrier board, the lead-out terminal of an outgoing wire may be connected to a receiving-board wiring pad, and the top wiring pad may be connected to another receiving-board wiring pad. FIG. 5F illustrates a schematic cross-section view of a corresponding semiconductor structure consistent with some embodiments of the present disclosure.

Referring to FIG. 5F, a plurality of outgoing wires 250 may be provided for each individual imaging device. For example, the lead-in terminal of each outgoing wire 250 may be connected to an input/output wiring pad 131, and the lead-out terminal of the outgoing wire 250 may extend out from the imaging device. A carrier board 300 may be provided, and the carrier board 300 may include a plurality of receiving-board wiring pads 310. The imaging device may be stuck to the carrier board 300 with the bottom surface of the imaging device facing to the carrier board 300. Further, a plurality of auxiliary devices 410 may be provided, and a top wiring pad 411 may be disposed on the top of each auxiliary device 410. The plurality of auxiliary devices 410 may be stuck to the carrier board 300 with the back surfaces of the auxiliary devices 410 facing to the carrier board 300. The lead-out terminal of an outgoing wire 250 may be connected to a receiving-board wiring pad 310, and the top wiring pad 411 may be connected to another receiving-board wiring pad 310 among the plurality of receiving-board wiring pads 310.

In one embodiment, through the steps S1-S6 described above, an imaging device may be obtained. Further, through the following step, i.e. step S7, a camera module containing the imaging device may be formed.

Referring to FIG. 6, in S7, an assembly of lens holder and lens may be disposed on the carrier board, the assembly of lens holder and lens including a lens holder, a lens group, and a micro focus motor. FIG. 5G illustrates a schematic cross-section view of a corresponding semiconductor structure consistent with some embodiments of the present disclosure.

Referring to FIG. 5G, an assembly of lens holder and lens may be disposed on the carrier board 300. The assembly of lens holder and lens may include a lens holder, a lens group, and a micro focus motor.

In one embodiment, in step S3, the second surface of the selective filter wafer 60 may be bonded to the first surface of the bottom wafer 50 through optical alignment along the vertical direction.

The present disclosure also provides another method for fabricating imaging devices. In one embodiment, only steps S5 and S6 of the method according to the embodiment described here may be different from the corresponding steps of a method according to the embodiment described above with reference to FIGS. 5A-5G; moreover, other steps may be substantially the same in both methods.

In one embodiment, in step S5, the bonded bottom wafer and selective filter wafer may be cut into a plurality of individual imaging devices along the plurality of scribed lines 140 of the bottom wafer; and when cutting the bonded bottom wafer and selective filter wafer, a side carrier board 500 (referring to FIG. 4A and FIG. 4B) connected to the image sensor chip 100 may be formed on the outer periphery of the image sensor chip 100.

In step S6, a plurality of outgoing wires 250 may be provided for each individual imaging device. The lead-in terminal of each outgoing wire 250 may be connected to an input/output wiring pad 131. A plurality of auxiliary devices 410 may be provided, and a top wiring pad 411 may be disposed on the top of each auxiliary device 410. An insulating carrier 510 (referring to FIG. 4B) may be formed on the outer periphery of an individual imaging device and the auxiliary devices 410. The insulating carrier 510 may be connected to the individual imaging device and the auxiliary devices 410, and thus form the side carrier board 500. The lead-out terminal of each outgoing wire 250 may be connected to a corresponding top wiring pad 141.

Further, a camera module containing the imaging device may be formed through the following step, i.e., step S7.

In step S7, an assembly of lens holder and lens may be disposed on the side carrier board 500. The assembly of lens holder and lens may include a lens holder, a lens group, and a micro focus motor.

The present disclosure also provides another method for fabricating imaging devices. In one embodiment, only steps S1 and S2 of the method according to the embodiment described here may be different from the corresponding steps of a method according to the embodiment described above with reference to FIGS. 5A-5G, and the other steps may be substantially the same in both methods.

According to the disclosed fabrication method, in step S1, a bottom wafer may be provided. A first surface of the bottom wafer may be divided into multiple regions by a plurality of scribed lines with each region including an image sensor chip. The first surface may be a photosensitive surface of the image sensor chip. Each image sensor chip may include a photosensitive region, a peripheral transition region surrounding the photosensitive region, and an input/output wiring region surrounding the peripheral transition region. Moreover, a plurality of retaining walls may be formed on the first surface of the bottom wafer in the peripheral transition region of each image sensor chip.

In step S2, a selective filter wafer, including a second surface and a third surface, may be provided. The selective filter wafer may not include any retaining walls formed on the second surface.

Compared to the formation of the retaining walls on the second surface of the selective filter wafer according to the method described above with reference to FIGS. 5A-5G, in the method disclosed here, the retaining walls may be formed on the first surface of the bottom wafer in the peripheral transition region of each image sensor chip. Therefore, in step S3, when bonding the second surface of the selective filter wafer to the first surface of the bottom wafer, the second surface of the selective filter wafer may be bonded to the retaining walls formed on the first surface of the bottom wafer. In one embodiment, the second surface of the selective filter wafer may be bonded to the first surface of the bottom wafer through vertical optical alignment. After bonding the selective filter wafer to the bottom wafer, a plurality of closed cavities may be formed above the photosensitive region of the chip.

In step S4, the portion of the selective filter wafer outside of the retaining walls may be removed to expose the input/output wiring regions of the image sensor chips. In the meantime, a plurality of selective filter covers may be formed from the selective filter wafer.

Further, in step S5, the bonded bottom wafer and selective filter wafer may be cut into a plurality of individual imaging devices along the plurality of scribed lines of the bottom wafer.

In step S6, for each individual imaging device, a plurality of outgoing wires may be provided. Each outgoing wire may include a lead-in terminal and a lead-out terminal. The lead-in terminal of the outgoing wire may be connected to an input/output wiring pad, and the lead-out terminal of the outgoing wire may extend out from the image sensor chip. As such, an imaging device may be obtained.

Further, in step S7, an assembly of lens holder and lens may be disposed on the carrier board to form a camera module containing the imaging device. The assembly of lens holder and lens may include a lens holder, a lens group, and a micro focus motor.

Various embodiments of the present disclosure have been described above, and the description above is illustrative, not exhaustive, and is not limited to the disclosed embodiments. Without departing from the scope of the invention, various modifications and changes should be apparent to those skilled in the art.

Compared to conventional imaging devices, camera modules, and fabrication methods, the disclosed imaging devices, camera modules, and fabrication methods may demonstrate several advantages.

According to the disclosed s imaging devices, camera modules, and fabrication methods, a selective filter cover is disposed above the photosensitive region of an imaging sensor chip, and a plurality of retaining walls are formed in the peripheral transition region that surrounds the photosensitive region. A plurality of closed cavities are formed by the selective filter cover and the plurality of retaining walls, and thus seal the photosensitive region of the chip, preventing dust and other foreign objects from falling into the photosensitive region of the chip and further affecting the photosensitive and imaging functions.

According to the disclosed s imaging devices, camera modules, and fabrication methods, the selective filter cover is removed from the module assembly of lens holder and lens. By disposing the selective filter cover into the imaging device, the vertical height of the module assembly of lens holder and lens can be effectively reduced, and thus the size of the entire camera module is reduced.

According to the disclosed s imaging devices, camera modules, and fabrication methods, prior to cutting the plurality of image sensor chips into individual image sensor chips, a selective filter wafer is placed onto the bottom wafer to prevent dust and other foreign objects from falling into the photosensitive region of the chip and further affecting the photosensitive and imaging functions during the subsequent packaging and assembly process.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. An imaging device, comprising:
an image sensor chip, including a photosensitive surface and, opposite to the photosensitive surface, a bottom surface, wherein the photosensitive surface includes a sensitive region, a peripheral transition region surrounding the photosensitive region, and an input/output wiring region surrounding the peripheral transition region, and at least one input/output wiring pad is disposed in the input/output wiring region;
a selective filter cover, disposed above the photosensitive region;
a retaining wall, disposed in the peripheral transition region and bonded to the selective filter cover, wherein the retaining wall and the selective filter cover together form a closed cavity above the photosensitive region; and
a plurality of outgoing wires, wherein a terminal of each outgoing wire is connected to an input/output wiring pad, and another terminal of the outgoing wire extends out from the image sensor chip.

2. The imaging device according to claim 1, wherein the image sensor chip is a complementary metal-oxide-semiconductor (CMOS) image sensor chip.

3. The imaging device according to claim 1, wherein:
the selective filter cover blocks or absorbs some or all external radiation in an infrared-band range and allows some or all radiation in a visible-light range to enter the photosensitive region.

4. The imaging device according to claim 1, wherein:
the retaining wall selectively blocks or absorbs some or all external radiation in an infrared-band range.

5. The imaging device according to claim 1, wherein:
an anti-reflection film is disposed on a surface of the selective filter cover to reduce reflection of radiation in a visible-light range.

6. The imaging device according to claim 1, wherein:
the selective filter cover is capable of refracting radiation in a visible-light range.

7. The imaging device according to claim 1, further including a color filter array disposed on a surface of the photosensitive region, wherein:
the color filter array includes a plurality of primary color filter units; and
the color filter array is made of a dyed polymer, wherein:
the plurality of primary color filter units include red, green, and blue primary color filter units, or include magenta, yellow, and cyan primary color filter units.

8. The imaging device according to claim 1, further including a micro-lens array disposed on a surface of the photosensitive region, wherein:
the micro-lens array includes a plurality of micro-focus lenses; and
the plurality of micro-focus lenses are made of a polymer.

9. The imaging device according to claim 1, further including a carrier board and a plurality of auxiliary devices, wherein:
the bottom surface of the image sensor chip is stuck to the carrier board;
a top wiring pad is disposed on top of each auxiliary device; and
the auxiliary device is stuck to the carrier board with the top wiring pad facing a direction away from the carrier board.

10. The imaging device according to claim 9, further including a plurality of receiving-board wiring pads disposed on the carrier board, wherein:
a lead-out terminal of an outgoing wire is connected to one of the plurality of receiving-board wiring pads; and
the top wiring pad of an auxiliary device is connected to another receiving-board wiring pad among the plurality of receiving-board wiring pads.

11. The imaging device according to claim 9, wherein:
a lead-out terminal of each outgoing wire is connected to a top wiring pad of an auxiliary device.

12. The imaging device according to claim 1, further including a side carrier board, wherein:
the side carrier board includes a plurality of auxiliary devices and an insulating carrier surrounding the image sensor chip and the plurality of auxiliary devices;
a top wiring pad is disposed on top of each auxiliary device; and
a lead-out terminal of each outgoing wire is connected to a top wiring pad through a surface of the side carrier board.

13. A camera module, comprising an imaging device according to claim 1.

14. A fabrication method for an imaging device, comprising:
providing a bottom wafer including a first surface, wherein
the first surface of the bottom wafer includes a plurality of image sensor chips;
each image sensor chip including a photosensitive surface and, opposite to the photosensitive surface, a bottom surface;
the first surface is the photosensitive surface;
the photosensitive surface includes a sensitive region, a peripheral transition region surrounding the photosensitive region, and an input/output wiring region surrounding the peripheral transition region; and
at least one input/output wiring pad is disposed in the input/output wiring region;
providing a selective filter wafer, including a second surface and a third surface;
forming a plurality of retaining walls on the second surface of the selective filter wafer with a number and a size corresponding to a number and a size of the image sensor chips disposed on the first surface of the bottom wafer, respectively, or on the first surface of the bottom wafer in the peripheral transition regions of the plurality of image sensor chips;
bonding the first surface of the bottom wafer to the second surface of the selective filter wafer, wherein the bottom wafer, the selective filter wafer, and the plurality of retaining walls together form a plurality of closed cavities above the photosensitive region;
removing a portion of the selective filter wafer located outside of the plurality of retaining walls to expose the input/output wiring region of each image sensor chip and form a selective filter cover corresponding to the image sensor chip;
cutting the bottom wafer and the selective filter wafer to obtain a plurality of individual imaging devices;
providing outgoing wires for an imaging device, wherein each outgoing wire includes a lead-in terminal and a lead-out terminal, the lead-in terminal of an outgoing wire is connected to an input/output wiring pad, the lead-out terminal of the out-going wire extends out from the image sensor chip.

15. The fabrication method according to claim 14, wherein:
the first surface of the bottom wafer is bonded to the second surface of the selective filter wafer through optical alignment along a vertical direction.

16. The fabrication method according to claim 14, wherein:
the first surface of the bottom wafer is divided into multiple regions by a plurality of scribed lines with each region including an image sensor chip; and
cutting the bottom wafer and the selective filter wafer along the plurality of scribed lines to obtain the plurality of individual imaging devices.

17. The fabrication method according to claim 14, after cutting the bottom wafer and the selective filter wafer to obtain the plurality of individual imaging devices, further including:
providing a carrier board;
sticking a bottom surface of an imaging device onto the carrier board;
providing a plurality of auxiliary devices, wherein a top wiring pad is disposed on top of each auxiliary device; and
sticking a bottom surface of each auxiliary device onto the carrier board.

18. The fabrication method according to claim 17, wherein the carrier board includes a plurality of receiving-board wiring pads, and the method further includes:
connecting the lead-out terminal of the outgoing wire to one of the plurality of receiving-board wiring pads; and
connecting the top wiring pad of an auxiliary device to another receiving-board wiring pad among the plurality of receiving-board wiring pads.

19. The fabrication method according to claim 17, further including:
connecting the lead-out terminal of the outgoing wire to a top wiring pad.

20. The fabrication method according to claim 14, after cutting the bottom wafer and selective filter wafer to obtain the plurality of individual imaging devices, further including:
providing a plurality of auxiliary devices, wherein a top wiring pad is disposed on top of each auxiliary device;
forming a side carrier board by forming an insulating carrier surrounding and connected to the imaging device and the plurality of auxiliary devices;
connecting the lead-out terminal of the outgoing wire to a top wiring pad through the side carrier board.
